(19) United States
(12) Patent Application Publication
(10) Pub. No.: US 2026/0298303 A1
(43) Pub. Date: Oct. 1, 2026

(54) COLOURED BARREL SPRING

(71) Applicant: NIVAROX-FAR S.A., Le Locle (CH)

(72) Inventors: Ivan VILLAR, Brügg (CH); Gregory KISSLING, La Neuveville (CH); Roger JUILLET, Fontainemelon (CH)

(73) Assignee: NIVAROX-FAR S.A., Le Locle (CH)

(21) Appl. No.: 19/552,340

(22) Filed: Feb. 27, 2026

(30) Foreign Application Priority Data
Mar. 28, 2025 (EP) 25166985.9

(51) Int. Cl. F16F 1/10; C23C 28/04

(52) U.S. Cl. CPC F16F 1/10; C23C 28/042; F16F 2224/0208; F16F 2226/02; F16F 2232/02; F16F 2236/08

(57) ABSTRACT

A barrel spring (1) including a substrate (4) coated with a layer (2) of Al₂O₃ and/or with a layer (3) of TiO₂ with a total thickness for all of the layers less than or equal to 125 nm in order to obtain a colour by interference effect.

### CROSS REFERENCE TO RELATED APPLICATIONS

This application claims priority to European Patent Application No. 25166985.9, filed on Mar. 28, 2025, the entire contents of which are incorporated herein by reference.

### TECHNICAL FIELD OF THE INVENTION

The present invention relates to a coloured barrel spring and in particular to a blue barrel spring.

### TECHNOLOGICAL BACKGROUND

Barrel spring blades are historically made of carbon steel, maraging steel, austenitic stainless steel type 1.4310 or cobalt-based austenitic alloy such as Nivaflex. These materials have a natural metallic grey colour that is generally not altered by the manufacturer of complete springs or barrels.

It is likely that thermally-blued carbon steel springs were manufactured in the past. Thermal bluing works poorly for austenitic steels or for cobalt-based austenitic alloys due to their good oxidation resistance.

### SUMMARY OF THE INVENTION

The purpose of the present invention is to overcome these disadvantages by proposing a barrel spring with an interference colouring.

To do this, it is proposed to apply a layer of Al₂O₃ and/or a layer of TiO₂ within a given thickness range to obtain an interference colour and in particular a blue colour.

Advantageously, the barrel spring is successively coated with a layer of Al₂O₃ and a layer of TiO₂, the outer layer of TiO₂ having the advantage of being more moisture-resistant while the method of applying the inner layer of Al₂O₃ has the advantage of being highly reproducible.

The resulting barrel spring has a very deep, consistent and uniform blue colour despite the complex geometry of a barrel spring. According to the invention, this deep, uniform blue colour can be obtained without the need to apply an undercoat on the base material of the substrate forming the barrel spring. Thus, the layer of TiO₂ or Al₂O₃ is in direct contact with the surface of the barrel spring.

In addition, this interference layer makes it possible to improve the wear resistance of the barrel spring by reducing friction between the coils.

### BRIEF DESCRIPTION OF THE FIGURES

FIG. 1 shows a barrel spring.

FIG. 2 schematically depicts, with a cross-sectional view, the interference layer on the barrel spring according to a variant of the invention.

FIG. 3 schematically depicts, with a cross-sectional view, the two interference layers on the barrel spring according to another variant of the invention.

### DETAILED DESCRIPTION OF THE INVENTION

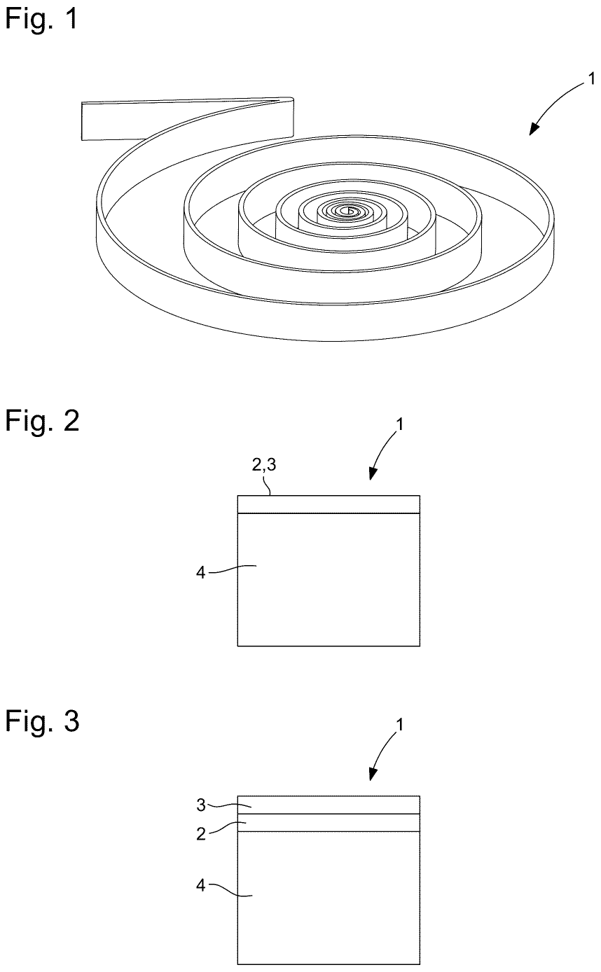

As shown in FIGS. 1 to 3, the present invention relates to a barrel spring 1 having a substrate 4 coated with a layer 2 of Al₂O₃ and/or with a layer 3 of TiO₂ with, for all the layers, a thickness of less than or equal to 125 nm in order to obtain an interference effect. In the presence of an Al₂O₃ layer and a TiO₂ layer, the substrate is preferably successively coated with a first layer 2 of Al₂O₃ and with a second layer 3 of TiO₂. According to the invention, each of the layers is advantageously applied by ALD (Atomic Layer Deposition). Preferably, the layer of TiO₂ or Al₂O₃ is in direct contact with the substrate surface. Although not limiting, the substrate material is more specifically a carbon steel, a maraging steel, an austenitic stainless steel for example type 1.4310 or an austenitic cobalt-based alloy such as Nivaflex®.

In the presence of a single layer on the substrate 4 according to the variant of FIG. 2, the layer 3 of TiO₂ has a thickness between 30 and 70 nm, preferably between 35 and 55 nm, more preferentially between 40 and 52 nm, even more preferentially between 48 and 52 nm to obtain a deep blue colour. Particularly preferably, the TiO₂ layer has a thickness of 50 nm.

In the presence of a single layer on the substrate 4 according to the variant of FIG. 2, the layer 2 of Al₂O₃ has a thickness between 75 and 125 nm, preferably between 90 and 110 nm, more preferentially between 95 and 105 nm, even more preferentially between 98 and 102 nm to obtain a deep blue colour. Particularly preferably, the Al₂O₃ layer has a thickness of 100 nm.

In the presence of a first layer 2 of Al₂O₃ and a second layer 3 of TiO₂ according to the variant of FIG. 3, the first layer of Al₂O₃ has a thickness between 10 and 50 nm and the second layer of TiO₂ has a thickness between 10 and 45 nm. Preferably, the first layer of Al₂O₃ has a thickness between 30 and 40 nm and the second layer of TiO₂ has a thickness between 20 and 40 nm. More preferably, the first layer of Al₂O₃ has a thickness of between 32 and 38 nm and the second layer of TiO₂ has a thickness of between 25 and 35 nm. Particularly preferably, the Al₂O₃ layer has a thickness of 35 nm and the TiO₂ layer has a thickness of 28 nm.

It will be specified that the analysis of the chemical composition of the layer(s) may be performed by EDX (Energy Dispersive X-ray Spectrometer) while the thickness of the layer(s) may be measured by ellipsometry.

1. A barrel spring comprising a substrate coated with a layer of Al2O3 and/or with a layer of TiO2 with a total thickness for all layers less than or equal to 125 nm in order to obtain a colour by interference effect.

2. The barrel spring according to claim 1, wherein the substrate is coated with a layer of Al₂O₃ having a thickness of between 75 and 125 nm.

3. The barrel spring according to claim 2, wherein the layer of Al₂O₃ has a thickness of between 90 and 110 nm.

4. The barrel spring according to claim 2, wherein the layer of Al₂O₃ has a thickness between 95 and 105 nm.

5. The barrel spring according to claim 2, wherein the layer of Al₂O₃ has a thickness of between 98 and 102 nm.

6. The barrel spring according to claim 1, wherein the substrate is coated with a layer of TiO₂ having a thickness between 30 and 70 nm.

7. The barrel spring according to claim 6, wherein the layer of TiO₂ has a thickness of between 35 and 55 nm.

8. The barrel spring according to claim 6, wherein the layer of TiO₂ has a thickness of between 40 and 52 nm.

9. The barrel spring according to claim 6, wherein the layer of TiO₂ has a thickness of between 48 and 52 nm.

10. The barrel spring according to claim 1 wherein the substrate is successively coated with a layer of Al₂O₃ and with a layer of TiO_{2,} said layer of Al₂O₃ having a thickness between 10 and 50 nm and said layer of TiO₂ having a thickness between 10 and 45 nm.

11. The barrel spring according to claim 10, wherein said layer of Al₂O₃ has a thickness of between 30 and 40 nm and said layer of TiO₂ has a thickness of between 20 and 40 nm.

12. The barrel spring according to claim 10, wherein said layer of Al₂O₃ has a thickness of between 32 and 38 nm and said layer of TiO₂ has a thickness of between 25 and 35 nm.

13. The barrel spring according to claim 1, wherein the substrate is made in carbon steel, maraging steel, austenitic stainless steel or austenitic cobalt-based alloy.

14. The barrel spring according to claim 1, wherein said layer of Al₂O₃ or said layer of TiO₂ is in direct contact with the substrate surface.
